(19) United States
(12) Patent Application Publication
(10) Pub. No.: US 2020/0313053 A1
(43) Pub. Date: Oct. 1, 2020

(54) HIGH POWER LED ASSEMBLY AND METHOD OF FORMING A HIGH POWER LED ASSEMBLY

(71) Applicant: LUMILEDS HOLDING B. V., Schiphol (NL)

(72) Inventors: Walter Daeschner, San Jose, CA (US); Chong Tat Lim, San Jose, CA (US); Tyan-Shin Go, San Jose, CA (US); Cheng Loong Yong, San Jose, CA (US); Aik-Teng Tan, San Jose, CA (US); Werner Goetz, San Jose, CA (US)

(73) Assignee: Lumileds Holding B.V., Schiphol (NL)

(21) Appl. No.: 16/370,936

(22) Filed: Mar. 30, 2019

(51) Int. Cl. H01L 33/62; H01L 33/50; H01L 33/56; H01L 33/60; H01L 27/15; H01L 33/00

(52) U.S. Cl. CPC H01L 33/62; H01L 33/50; H01L 33/005; H01L 33/60; H01L 27/153; H01L 33/56

(57) ABSTRACT

Systems, apparatus and methods of forming an LED device are described herein. The method includes providing a lead frame and an LED sub-assembly including an LED die attached to a wavelength converting layer, and an optically transparent side wall surrounding the LED die, the optically transparent side wall having a curved or angled profile, attaching the LED sub-assembly to the lead frame, and dispensing an encapsulation material in a space surrounding the LED sub-assembly attached to the lead frame. The LED assembly is a high power LED assembly.

### BACKGROUND

There are two general power classifications for light emitting diode (LED) devices: low/medium power LED devices and high power LED devices. These two classes of LEDs can be manufactured in different ways and require different assembly processes to provide the desired characteristics typically associated with each class of LED device.

### SUMMARY

Systems, apparatus and methods of forming an LED device are described herein. The method includes providing a lead frame and an LED sub-assembly including an LED die attached to a wavelength converting layer, and an optically transparent side wall surrounding the LED die, the optically transparent side wall having a curved or angled profile, attaching the LED sub-assembly to the lead frame, and dispensing an encapsulation material in a space surrounding the LED sub-assembly attached to the lead frame. The LED assembly is a high power LED assembly.

### BRIEF DESCRIPTION OF THE DRAWINGS

The foregoing Summary as well as the following Detailed Description will be best understood when read in conjunction with the appended drawings. In the drawings:

FIG. 1A is a cross-sectional view of an example LED device;

FIG. 1B is a cross-sectional view of another example LED device;

FIG. 1C is a photograph of a cross-section of an example LED device;

FIG. 1D is a photograph of a cross-section of another example LED device;

FIGS. 1E-1I are schematic drawings illustrating an example method of producing an LED device;

FIG. 1J is a flow diagram of an example method of producing an LED device;

FIG. 2A is a diagram showing an Light Emitting Diode (LED) device;

FIG. 2B is a diagram showing multiple LED devices;

FIG. 3 is a top view of an electronics board for an integrated LED lighting system according to one embodiment;

FIG. 4A is a top view of the electronics board with LED array attached to the substrate at the LED device attach region in one embodiment;

FIG. 4B is a diagram of one embodiment of a two channel integrated LED lighting system with electronic components mounted on two surfaces of a circuit board; and

FIG. 5 is a diagram of an example application system.

### DETAILED DESCRIPTION OF THE PREFERRED EMBODIMENTS

Examples of different light illumination systems and/or light emitting diode implementations will be described more fully hereinafter with reference to the accompanying drawings. These examples are not mutually exclusive, and features found in one example may be combined with features found in one or more other examples to achieve additional implementations. Accordingly, it will be understood that the examples shown in the accompanying drawings are provided for illustrative purposes only and they are not intended to limit the disclosure in any way. Like numbers refer to like elements throughout.

It will be understood that, although the terms first, second, third, etc. may be used herein to describe various elements, these elements should not be limited by these terms. These terms may be used to distinguish one element from another. For example, a first element may be termed a second element and a second element may be termed a first element without departing from the scope of the present invention. As used herein, the term “and/or” may include any and all combinations of one or more of the associated listed items.

It will be understood that when an element such as a layer, region, or substrate is referred to as being “on” or extending “onto” another element, it may be directly on or extend directly onto the other element or intervening elements may also be present. In contrast, when an element is referred to as being “directly on” or extending “directly onto” another element, there may be no intervening elements present. It will also be understood that when an element is referred to as being “connected” or “coupled” to another element, it may be directly connected or coupled to the other element and/or connected or coupled to the other element via one or more intervening elements. In contrast, when an element is referred to as being “directly connected” or “directly coupled” to another element, there are no intervening elements present between the element and the other element. It will be understood that these terms are intended to encompass different orientations of the element in addition to any orientation depicted in the figures.

Relative terms such as “below,” “above,” “upper,”, “lower,” “horizontal” or “vertical” may be used herein to describe a relationship of one element, layer, or region to another element, layer, or region as illustrated in the figures. It will be understood that these terms are intended to encompass different orientations of the device in addition to the orientation depicted in the figures.

Semiconductor light emitting devices or optical power emitting devices, such as devices that emit ultraviolet (UV) or infrared (IR) optical power, are among the most efficient light sources currently available. These devices may include light emitting diodes, resonant cavity light emitting diodes, vertical cavity laser diodes, edge emitting lasers, or the like (hereinafter referred to as “LEDs”). Due to their compact size and lower power requirements, for example, LEDs may be attractive candidates for many different applications. For example, they may be used as light sources (e.g., flash lights and camera flashes) for hand-held battery-powered devices, such as cameras and cell phones. They may also be used, for example, for automotive lighting, heads up display (HUD) lighting, horticultural lighting, street lighting, torch for video, general illumination (e.g., home, shop, office and studio lighting, theater/stage lighting and architectural lighting), augmented reality (AR) lighting, virtual reality (VR) lighting, as back lights for displays, and IR spectroscopy. A single LED may provide light that is less bright than an incandescent light source, and, therefore, multi-junction devices or arrays of LEDs (such as monolithic LED arrays, micro LED arrays, etc.) may be used for applications where more brightness is desired or required. Additionally or alternatively, LEDs with increasing active area size may be generated. Multiple LEDs may be combined to replace a legacy light source.

LED devices may be formed by combining an LED sub-assembly with a lead frame. High power LED devices typically require an interposer formed from a ceramic substrate. The lead frame discussed in accordance with the subject matter disclosed herein is an implementation of such an interposer. While ceramic substrates are well suited for high power LED devices, ceramic substrates also have size restrictions, and are costly, which may result in constraints during production that limit the manufacturing processes that can be applied to mass produce high power LED devices with ceramic substrates. As a result, manufacturing LED devices with lead frames with ceramic substrates is expensive and time consuming to manufacture. Accordingly, it may be desirable to provide a high power LED assembly that is cost-effective to manufacture that also has efficient light extraction features while maintaining all desirable features of a high efficiency, high power LED.

The present embodiments broadly disclose integrating an LED (e.g., high powered LED) sub-assembly with a lead frame assembly (e.g., high volume lead frame assembly). The embodiments disclosed herein have the high performance characteristics of high power LEDs but are relatively inexpensive and easy to manufacture.

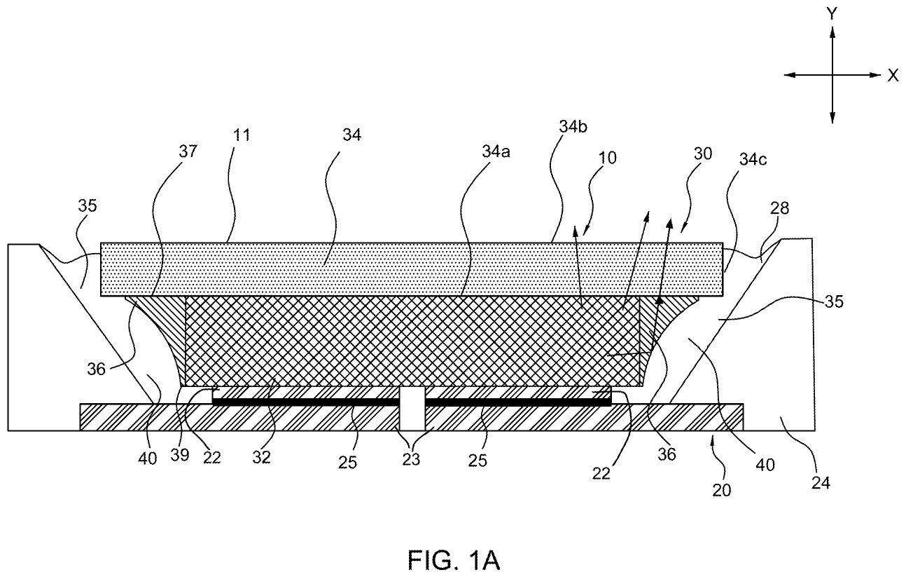

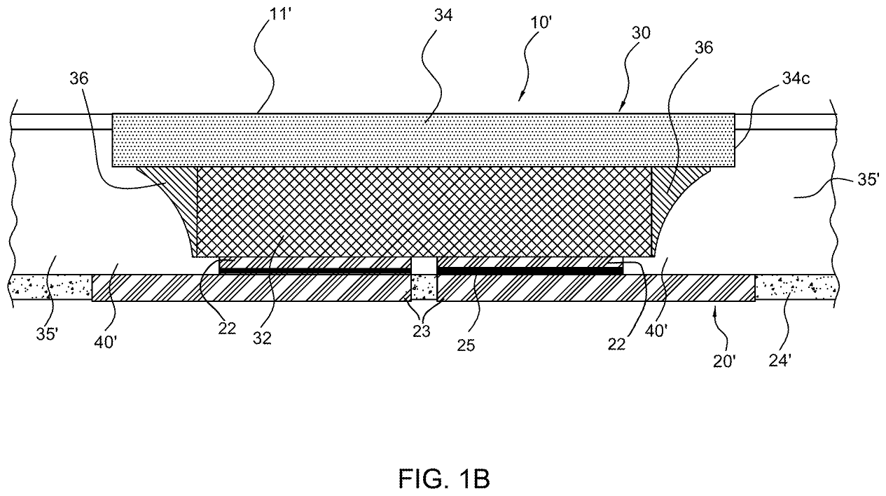

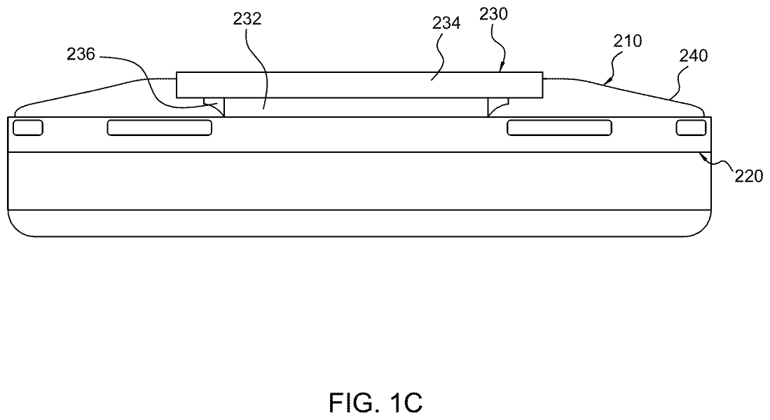

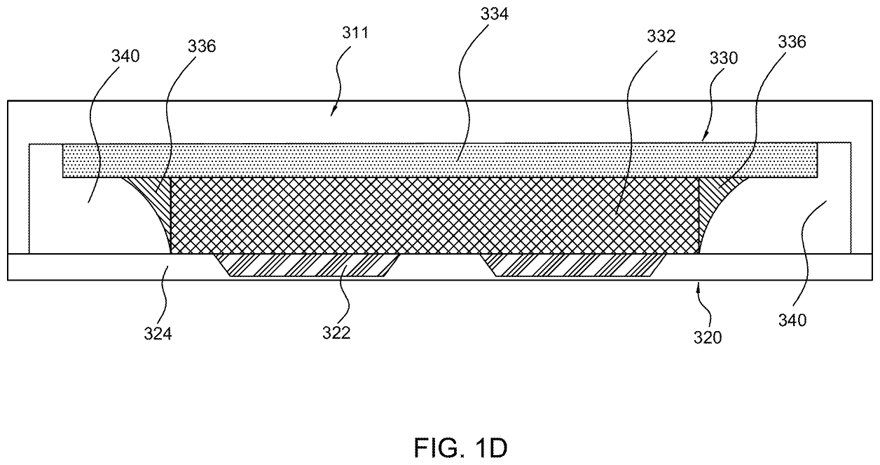

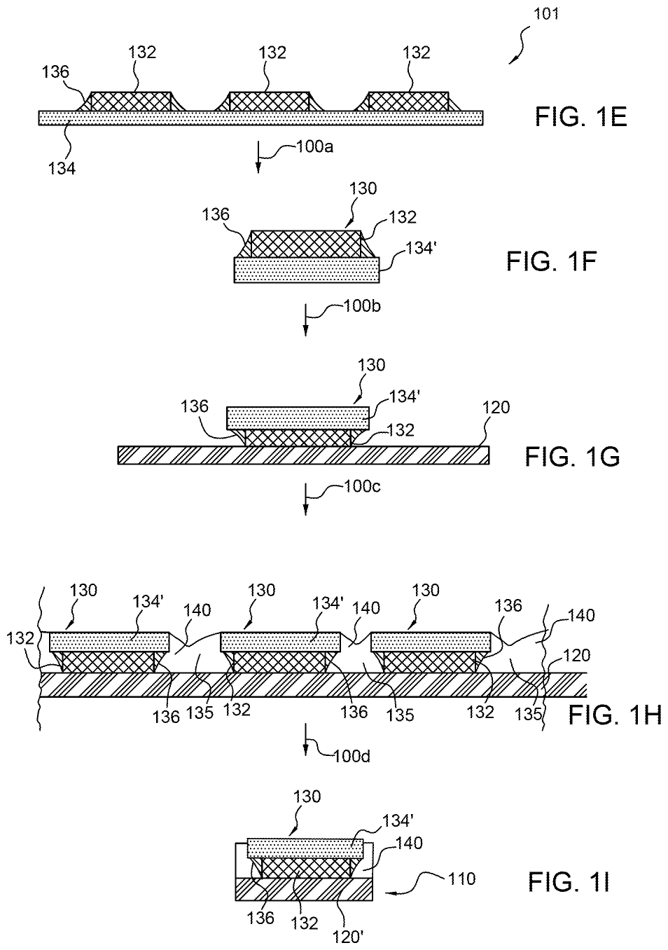

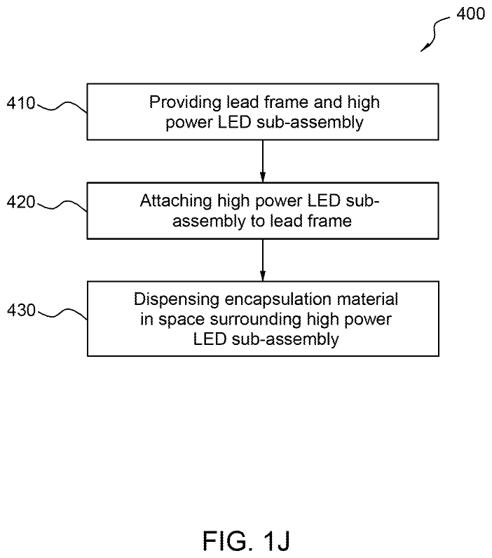

FIG. 1A is a diagram of an example LED device 10. The illustrated LED device 10 may be a high power LED device. As used herein, the term high power LED device may refer to an LED device having a construction that enables driving the LED device at an input power of greater than, for example, one watt and, for example, provides a concentrated beam from a small optical source size. A high power LED's construction may provide, for example, high luminance from a single package to enable cost effective, single optic and directional fixture designs. A high power LED device, as disclosed herein, may include lead frame or base material formed by, for example, an epoxy moulding compound (EMC) process or silicon molding compound In accordance with the disclosed subject matter, the light extraction features, In comparison, a low or mid power LED may be constructed of material such as plastic frames which would not enable the performance, as disclosed herein. In a high power LED device, the light extraction features, which are part of the LED sub-assembly 30 before the LED sub-assembly 30 is attached to the lead frame 20, may enable use of the epoxy or silicone molding compound. As an example, in traditional LED devices, it may be necessary to place a hemispherical dome onto the LED, increasing the difficulty of the manufacturing process; as such a process may be achieved by using a ceramic substrate as a carrier, which may increase the difficulty and/or cost of the process. According to implementations disclosed herein, parts (e.g., metal parts such as copper) which enable effective heat transfer are used. Further, the epoxy or silicone molding compound may act as an electrical insulator while mechanically providing stability for the parts (e.g., metal parts such as copper) which may be needed for thermal and electrical conductivity.

The LED device 10 illustrated in FIG. 1A includes a lead frame 20, an LED sub-assembly 30, and an encapsulation layer or material 40.

The lead frame 20 may include metallic contacts 22 embedded in a base 24. In one embodiment, metallic contacts 22 are formed from copper. The metallic contacts 22 can be formed from any suitable conductive material capable of directing current to the LED sub-assembly 30 and can be formed by an etching or stamping process. The base 24 of the lead frame 20 may be formed from a polymer. In one embodiment, the base 24 is formed by, for example, an epoxy moulding compound (EMC) process or silicon molding compound. The LED device 10 may emit light when current is provided by the lead frame 20.

In one embodiment, as best shown in FIG. 1A, the lead frame 20 includes a cavity or pocket 28. The pocket 28 can be formed as part of the moulding process or can be stamped or pressed into the base 24. This pocket 28 may be adapted and dimensioned to receive the LED sub-assembly 30.

The lead frame 20 includes interconnects 25 and frame 23, and generally serves as an integrated heat transferor, such as a heat transfer element, and part of the lead frame may be formed from copper. Interconnects 25 may be solder joints or other interconnect material that connect the metallic contacts 22 to the frame 23. The lead frame 20 may connect the LED device 10 to, for example, a PCB board. The thickness of the lead frame or a component of the lead frame may be limited due to etching or stamping based manufacturing technology. Further, there is an inherent trade-off between a gap between an anode and cathode solder pad and a thickness of the lead frame or component of the lead frame in that the gap generally cannot be made smaller than a total thickness of the lead frame or component of the lead frame. The embodiments of the LED assembly disclosed herein are based on a 200 μm gap and a 200 μm substrate thickness. However, other gap sizes and substrate thicknesses may be used consistent with the embodiments described herein. The lead frame 20 serves as a heat transferor as heat flows from the LED die 32 through the mechanical contacts 22, interconnects 25 and through the frame 23. Notably, heat is transferred in a horizontal direction across the frame 23 and this horizontal dissipation of heat allows the heat to spread and transfer more evenly and effectively into a circuit board and, from there, outwards to a heatsink. Accordingly, lead frame 20 serves as a heat spreader in accordance with the subject matter disclosed herein.

According to an implementation, one or more additional pads in addition to the mechanical contacts 22, such as a neutral pad (not shown), may be provided and may provide additional heat dissipation. Further, inside the lead frame 20 there may be a Zener diode (not shown) which may protect the LED die 32 against transient Voltage. Such a diode may be a Transient Voltage Suppressor (TVS).

While the lead frame 20 illustrated in FIG. 1A has a cavity formed therein to accommodate the LED sub-assembly, other shapes of lead frames are possible. For example, FIG. 1B is a cross-sectional view of another example LED device that has a lead frame 20′ formed as a continuously flat plate having a uniform cross-sectional profile. The term “continuously flat,” as used herein, may indicate that the lead frame 20′ has a generally flat and constant cross-sectional profile with the exception of varying cross-sections for the metallic contacts.

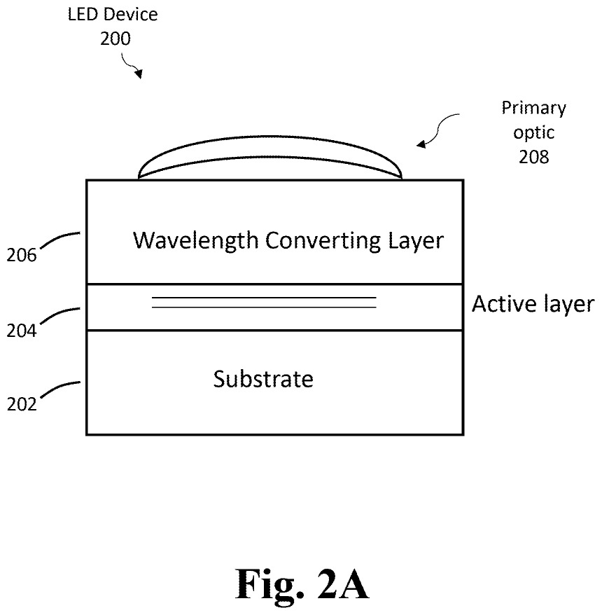

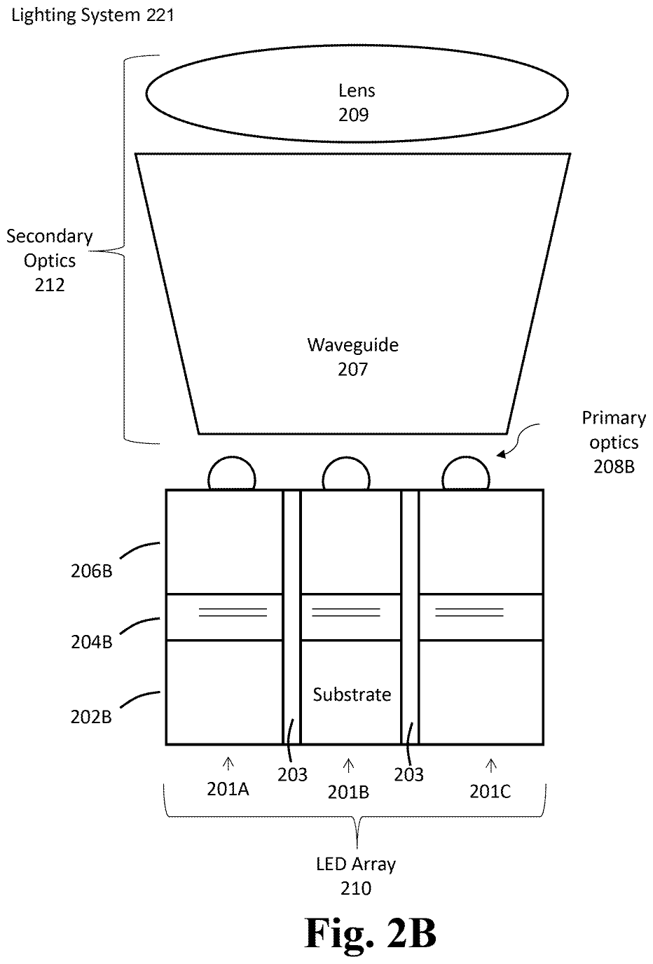

Referring back to FIG. 1A, the LED sub-assembly 30 includes an LED die 32, a wavelength converting layer 34, and a side wall 36. The LED die 32 may include the substrate 202 and active layer 204 illustrated in FIG. 2A and described in more detail below. The wavelength converting layer 34 may be the same as, or similar to, the wavelength converting layer 206 illustrated in FIG. 2A and described in detail below. The side wall 36 may surround the LED die 32 and may be formed from a transparent material to allow emitted light to not be emitted out of the LED device via the wavelength converting layer 206 but also to be emitted through a side wall of the LED and then transmitted through the sidewall 36, as shown by the arrows in FIG. 1A. The curvature of sidewall 36 may be optimized such that all or almost all (e.g., substantially all) photons exiting the die 32 are reflected towards the wavelength converting layer 206. The side wall 36 may have an angled or curved profile, which may promote flow of an encapsulation material 40 into the area surrounding the LED sub-assembly 30 between the LED sub-assembly 30 and the lead frame 20. As shown in FIG. 1A, the curve may be concave relative to the LED die 32. The side wall 36 may be optically transparent for a wavelength of interest. According to an implementation, the side wall 36 may be partially transparent for a wavelength of interest. A wavelength of interest may be the wavelength emitted by the LED die 32 and/or the light emitted after converting via the wavelength converting layer 34.

According to an implementation, wavelength converting layer 34 may not be present or may be replaced by a transparent layer (e.g., a layer that not contain wavelength converting particles) such that light is emitted by the LED die 32 is not converted and is emitted as is. In such an implementation, for example, the LED die 32 may emit blue light which is then emitted from the LED device 10 without being converted.

The side wall 36 has a height (measured along axis Y in FIG. 1A) that may be equal to or greater than a height of the LED die 32. The side wall 36 may also have a relatively wider base 37 that abuts the wavelength conversion layer 34 and a narrower end or tip 39 extending towards the lead frame 20. The wavelength conversion layer 34 may be wider than the LED die 32 (width being measured along the X-axis illustrated in FIG. 1A), and the LED die 32 may be thicker than the wavelength conversion layer 34 (thickness being measured along the Y-axis illustrated in FIG. 1A). One of ordinary skill in the art would understand that the relative sizes and dimensions of the LED sub-assembly 30 components can be varied depending on the specific requirements of a particular application.

The wavelength conversion layer 34 may have a generally flat profile defined by a first surface 34a adjacent the LED die 32 and a second surface 34b opposite from the first surface 34a. For example, the wavelength converting layer 34 may be a platelet (e.g., ceramic phosphor plate) or film. In contrast, a converter layer in low power or mid power LEDs is typically deposited on the LED die in the form of a sludge or paste, which may be a phosphor mixed with silicone. Thus, as compared to wavelength conversion layers in low power or mid power LEDs, the wavelength conversion 34 described herein may have a discrete and well-defined shape.

The LED sub-assembly 30 may be prepared as a package prior to installation with the lead frame 20. As used herein, the term package may refer to components that are attached or fixed to each other such that the package can be handled or picked up with each of the components attached or fixed to each other. According to an implementation, the LED sub-assembly 30 may be fully assembled prior to attachment to the lead frame 20.

The LED sub-assembly 30 may be a chip-scale package type LED sub-assembly. Direct contact between contacts of the LED sub-assembly 30 and the metal contacts 22 of the lead frame may provide highly efficient thermal resistance and does not require connection wires.

The encapsulation material 40 may be formed from a reflective material, such as a polymeric material mixed with reflective particles. The encapsulation material may surround the LED sub-assembly 30 to both reflect light emitted by the LED die 32 and stabilize the LED sub-assembly. The encapsulation material 40 preferably includes a polymeric material mixed with reflective particles. In one embodiment, the encapsulation material 40 may include silicone mixed with titanium oxide (TiOx) particles.

The encapsulation material 40 may be deposited into the space 35 surrounding the LED sub-assembly 30 between the LED sub-assembly 30 and the lead frame 20. The encapsulation material 40 can be sprayed, poured, or otherwise deposited into this space 35. The encapsulation material 40 may be deposited in the space 35 in an uncured state such that the encapsulation material 40 flows into the space 35 based on capillary action. In the uncured state, the encapsulation material 40 is fluid. Once the encapsulation material 40 fully surrounds the LED sub-assembly 30 and is settled, the encapsulation material 40 may be cured such that it hardens in place. The encapsulation material 40 can be cured via any known curing technique such as, for example, thermal or optical curing.

The rigidity of the encapsulation material 40 may reinforce the LED device 10 and protect the components within the LED sub-assembly 20. As shown in FIGS. 1A and 1B, the encapsulation material 40, 40′ covers a lateral surface 34c of the wavelength conversion layer 34. The space 35 can either have a conical profile as shown in FIG. 1A, or the space 35′ can have an open profile as shown in FIG. 1B.

Regarding the LED device 10′ illustrated in FIG. 1B, although not illustrated in FIG. 1B, the space 35′ may extend to an adjacent LED assembly. FIG. 1H, which is described in more detail below with respect to the method of producing, shows the space 135 having an open profile such that the space 135 extends between neighboring LED sub-assemblies. Based on the embodiments disclosed herein, the overall arrangement of LED sub-assemblies 30 on the lead frame 20 can be varied. In embodiments, such as in FIG. 1A where the lead frame 20 includes pockets 28, spacing between adjacent LED sub-assemblies 30 may be determined based on the orientation of the pockets 28. In embodiments, such as illustrated in FIG. 1B, where the lead frame 20 includes a flat base (i.e., lacking cavities or pockets), the LED sub-assemblies may be positioned in a variety of orientations on the lead frame 20. Once the LED sub-assemblies 30 are positioned on the lead frame 20, the encapsulation material 40 may be deposited to fill voids between the LED sub-assemblies 30.

The assembled LED assemblies 10, 10′ shown in FIGS. 1A and 1B have generally flat upper surfaces 11, 11′. The term generally flat as used herein with respect to this upper surface 11, 11′ may indicate that the upper surface 11, 11′ lacks any protrusions, bulges, domes, etc. The LED assembly described herein has comparable or improved extraction efficiency from conventional LED assemblies that include a hemispherical dome (without need for the dome).

As described herein, the LED assembly can be produced in a relatively large volume due to the lack of a ceramic substrate, which previously limited production to making the substrate in 4 inch×4 inch pieces. Further, the lead frame described herein can be produced in large volume based on the materials required to form the base.

FIG. 10 is a photograph of a cross-section of an assembled LED device 210. The lead frame 220, the LED sub-assembly 230, the die 232, the wavelength conversion layer 234, the side wall 236, and the encapsulation material 240 may each correspond to the lead frame 20, LED sub-assembly 30, die 32, converter layer 34, side wall 36, and encapsulation material 40 shown in FIGS. 1A and 1B.

FIG. 1D is a photograph of another example of a cross-section of an assembled LED device 311. The lead frame 321, contacts 322, base 324, LED sub-assembly 330, die 332, wavelength conversion layer 334, side wall 336, and encapsulation material 340 may each correspond to the lead frame 20, metallic contacts 22, base 24, LED sub-assembly 30, die 32, wavelength conversion layer 34, side wall 36, and encapsulation material 40 shown in FIGS. 1A and 1B.

FIGS. 1E-1I illustrate steps of a method 100 for forming an LED assembly 110. FIGS. 1E-1I illustrate five steps for manufacturing the LED assembly 110. One of ordinary skill in the art would understand that more or less steps can be involved. Additionally, any of the steps may be combined to be performed at the same time. The order of these steps can also be altered such that any one or more of the steps are performed in a different sequence than illustrated in FIGS. 1E-1I.

FIG. 1E illustrates a semi-finished LED sub-assembly including a wavelength conversion layer 134 sheet and a plurality of dies 132 deposited onto the wavelength conversion layer 134. Side walls 136 are deposited around the dies 132.

As shown in FIG. 1E, the wavelength conversion layer 134 may be diced to provide individual LED sub-assemblies 130 that include the die 132, the side wall 136, and a portion of the wavelength conversion 134′ (100a). This sub-assembly or package 130 can be individually handled.

As shown in FIG. 1F, the lead frame 120 may be attached to the LED package or sub-assembly 130 (100b). This attachment can be achieved via soldering or any other method. In embodiments, the lead frame 120 directly contacts the die 132, which may improve thermal resistance for the assembly.

As shown in FIG. 1G, multiple LED sub-assemblies 130 may be attached to the lead frame 120 (100c). Based on the placement of the LED sub-assemblies 130 on the lead frame 120, a space 135 may defined between adjacent LED sub-assemblies 130. This space 135 may be subsequently filled by depositing an encapsulation material 140. Once settled, the encapsulation material 140 may be cured and hardened.

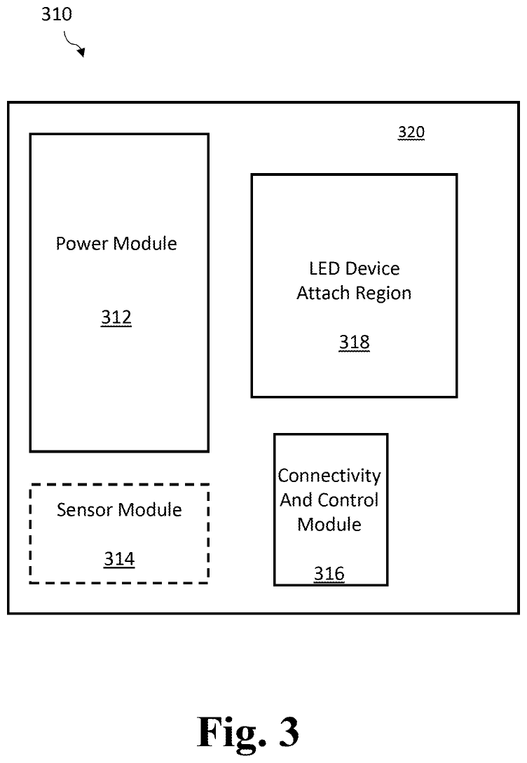

As shown in FIG. 1H, the structure formed by the multiple LED sub-assemblies 130 attached to the lead frame 120 may be diced to provide individual LED devices 110 (100d) such that an LED device 110 is fully formed. As shown in FIG. 1I, for example, the fully formed LED device 101 may include a single LED sub-assembly 130 (that may include the die 132, wavelength conversion layer 134′, and side wall 136), the lead frame 120′, and the encapsulation material 140. This LED device 110 may be handled for further processing or assembled into a larger LED array. Example LED systems are shown in FIGS. 3, 4A, 4B, 4C, 4D, 4E and 5, and described in detail below, that may include an LED array, or space for attachment of an LED array, that may include multiple LED devices as described above.

FIG. 1J is a flow diagram of a method 400 according to one embodiment. The method 400 may include providing a lead frame and a high power LED sub-assembly (410). The method 400 may further include attaching the high power LED sub-assembly to a lead frame (420). The method 400 may further include dispensing an encapsulation material in a space surrounding the high power LED sub-assembly (430). As mentioned generally above, the steps illustrated in this flow diagram can include more steps not explicitly shown in this figure.

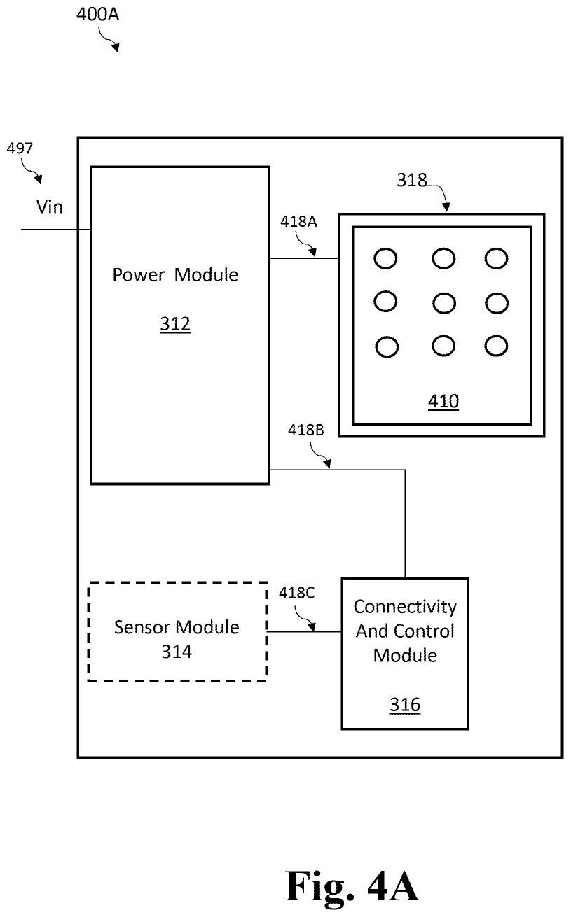

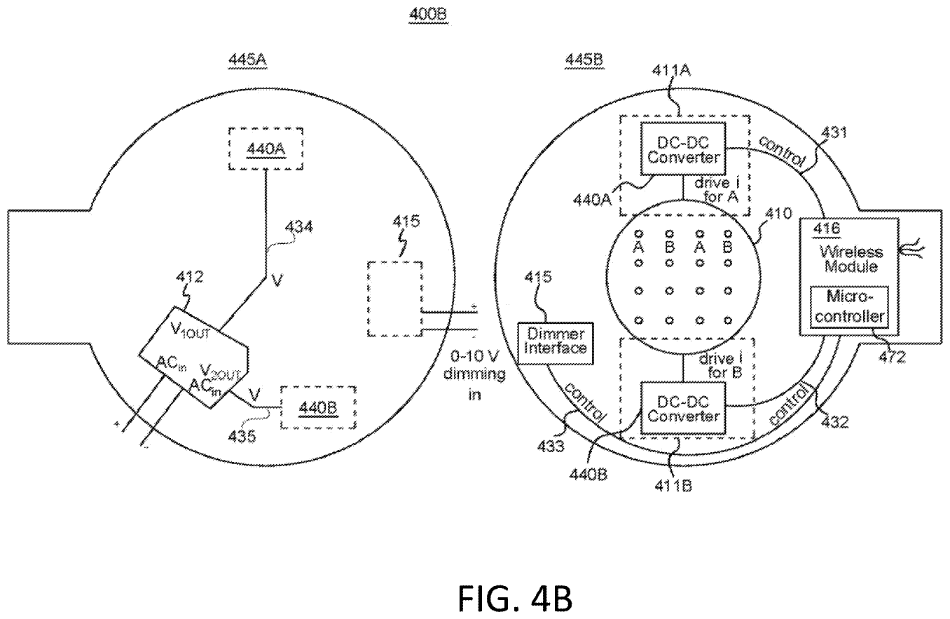

A method of operating a high power LED device, such as 10 or 10′ illustrated in FIGS. 1A and 1B may include supplying electrical current from the lead frame 20 to the LED die 32 via the metallic contact 22 such that the LED die 32 emits light. The emitted light (indicated by the arrows in FIG. 1A extending from the die 32) may be directed to the wavelength conversion layer 34, and through the side wall 36 to be reflected by the encapsulation material 40 back into the LED die and/or the wavelength conversion layer 34 for eventual down conversion by the wavelength conversion layer 34. Electrical current can be provided from an external power source and provide to the LED device via a DC/DC converter on the same or different electronics board on which the LED device is mounted. Example systems including a DC/DC converter, and possible arrangements of the DC/DC converter in relation to an LED array that may include a plurality of the LED devices described herein as pixels, on one or more electronics boards are shown in FIGS. 3, 4A, 4B, 4C, 4D and 4E and described in more detail below.

FIG. 2A is a diagram of an LED device 200 in an example embodiment. The LED device 200 may include a substrate 202, an active layer 204, a wavelength converting layer 206, and primary optic 208. In other embodiments, an LED device may not include a wavelength converter layer and/or primary optics. The substrate 202 and active layer 204 correspond to the die 32 as shown in FIGS. 1A and 1B.

As shown in FIG. 2A, the active layer 204 may be adjacent to the substrate 202 and emits light when excited. Suitable materials used to form the substrate 202 and the active layer 204 include sapphire, SiC, GaN, Silicone and may more specifically be formed from a III-V semiconductors including, but not limited to, AlN, AlP, AlAs, AlSb, GaN, GaP, GaAs, GaSb, InN, InP, InAs, InSb, II-VI semiconductors including, but not limited to, ZnS, ZnSe, CdSe, CdTe, group IV semiconductors including, but not limited to Ge, Si, SIC, and mixtures or alloys thereof.

The wavelength converting layer 206 may be remote from, proximal to, or directly above active layer 204. The active layer 204 emits light into the wavelength converting layer 206. The wavelength converting layer 206 acts to further modify wavelength of the emitted light by the active layer 204. LED devices that include a wavelength converting layer are often referred to as phosphor converted LEDs (“POLED”). The wavelength converting layer 206 may include any luminescent material, such as, for example, phosphor particles in a transparent or translucent binder or matrix, or a ceramic phosphor element, which absorbs light of one wavelength and emits light of a different wavelength. The wavelength converting layer may be the same as or similar to wavelength converting layer 34 of FIGS. 1A and 1B.

The primary optic 208 may be on or over one or more layers of the LED device 200 and allow light to pass from the active layer 204 and/or the wavelength converting layer 206 through the primary optic 208. The primary optic 208 may be a lens or encapsulate configured to protect the one or more layers and to, at least in part, shape the output of the LED device 200. Primary optic 208 may include transparent and/or semi-transparent material. In example embodiments, light via the primary optic may be emitted based on a Lambertian distribution pattern. It will be understood that one or more properties of the primary optic 208 may be modified to produce a light distribution pattern that is different than the Lambertian distribution pattern.

FIG. 2B shows a cross-sectional view of a lighting system 221 including an LED array 210 with pixels 201A, 201B, and 201C, as well as secondary optics 212 in an example embodiment. The LED array 210 includes pixels 201A, 201B, and 201C each including a respective wavelength converting layer 206B active layer 204B and a substrate 202B. The LED array 210 may be a monolithic LED array manufactured using wafer level processing techniques, a micro LED with sub-500 micron dimensions, or the like. Pixels 201A, 201B, and 2010, in the LED array 210 may be formed using array segmentation, or alternatively using pick and place techniques. Pixels 201A, 201B, and 201C may be similar to the pixels shown in FIG. 1H.

The spaces 203 shown between one or more pixels 201A, 201B, and 201C of the LED devices 200B may include an air gap or may be filled by a material such as a metal material which may be a contact (e.g., n-contact).

The secondary optics 212 may include one or both of the lens 209 and a reflector or waveguide 207. It will be understood that although secondary optics are discussed in accordance with the example shown, in example embodiments, the secondary optics 212 may be used to spread the incoming light (diverging optics), or to gather incoming light into a collimated beam (collimating optics). In example embodiments, the reflector or waveguide 207 may be a concentrator or a mixing device and may have any applicable shape to concentrate, diverge or direct light such as a parabolic shape, cone shape, beveled shape, or the like. The reflector or waveguide 207 may be coated with a dielectric material, a metallization layer, or the like used to reflect or redirect incident light. In alternative embodiments, a lighting system may not include one or more of the following: the wavelength converting layer 206B, the primary optics 208B, the reflector or waveguide 207 and the lens 209.

Lens 209 may be formed form any applicable transparent material such as, but not limited to SiC, aluminum oxide, diamond, or the like or a combination thereof. Lens 209 may be used to modify the a beam of light input into the lens 209 such that an output beam from the lens 209 will efficiently meet a desired photometric specification. Additionally, lens 209 may serve one or more aesthetic purpose, such as by determining a lit and/or unlit appearance of the p 201A, 201B and/or 201C of the LED array 210.

FIG. 3 is a top view of an electronics board 310 for an integrated LED lighting system according to one embodiment. In alternative embodiments, two or more electronics boards may be used for the LED lighting system. For example, the LED array may be on a separate electronics board, or the sensor module may be on a separate electronics board. In the illustrated example, the electronics board 310 includes a power module 312, a sensor module 314, a connectivity and control module 316 and an LED attach region 318 reserved for attachment of an LED array to a substrate 320.

The substrate 320 may be any board capable of mechanically supporting, and providing electrical coupling to, electrical components, electronic components and/or electronic modules using conductive connectors, such as tracks, traces, pads, vias, and/or wires. The power module 312 may include electrical and/or electronic elements. In an example embodiment, the power module 312 includes an AC/DC conversion circuit, a DC/DC conversion circuit, a dimming circuit, and an LED driver circuit.

The sensor module 314 may include sensors needed for an application in which the LED array is to be implemented.

The connectivity and control module 316 may include the system microcontroller and any type of wired or wireless module configured to receive a control input from an external device.

The term module, as used herein, may refer to electrical and/or electronic components disposed on individual circuit boards that may be soldered to one or more electronics boards 310. The term module may, however, also refer to electrical and/or electronic components that provide similar functionality, but which may be individually soldered to one or more circuit boards in a same region or in different regions.

FIG. 4A is a top view of the electronics board 310 with an LED array 410 attached to the substrate 320 at the LED device attach region 318 in one embodiment. The electronics board 310 together with the LED array 410 represents an LED system 400A. Additionally, the power module 312 receives a voltage input at Vin 497 and control signals from the connectivity and control module 316 over traces 418B, and provides drive signals to the LED array 410 over traces 418A. The LED array 410 is turned on and off via the drive signals from the power module 312. In the embodiment shown in FIG. 4A, the connectivity and control module 316 receives sensor signals from the sensor module 314 over trace 418C.

FIG. 4B illustrates one embodiment of a two channel integrated LED lighting system with electronic components mounted on two surfaces of a circuit board 499. As shown in FIG. 4B, an LED lighting system 400B includes a first surface 445A having inputs to receive dimmer signals and AC power signals and an AC/DC converter circuit 412 mounted on it. The LED system 400B includes a second surface 445B with the dimmer interface circuit 415, DC-DC converter circuits 440A and 440B, a connectivity and control module 416 (a wireless module in this example) having a microcontroller 472, and an LED array 410 mounted on it. The LED array 410 is driven by two independent single channels 411A and 411B. In alternative embodiments, a single channel may be used to provide the drive signals to an LED array, or any number of multiple channels may be used to provide the drive signals to an LED array.

The LED array 410 may include two groups of LED devices. In an example embodiment, the LED devices of group A are electrically coupled to a first channel 411A and the LED devices of group B are electrically coupled to a second channel 411B. Each of the two DC-DC converters 440A and 440B may provide a respective drive current via single channels 411A and 411B, respectively, for driving a respective group of LEDs A and B in the LED array 410. The LEDs in one of the groups of LEDs may be configured to emit light having a different color point than the LEDs in the second group of LEDs. Control of the composite color point of light emitted by the LED array 410 may be tuned within a range by controlling the current and/or duty cycle applied by the individual DC/DC converter circuits 440A and 440B via a single channel 411A and 411B, respectively. Although the embodiment shown in FIG. 4B does not include a sensor module (as described in FIG. 3 and FIG. 4A), an alternative embodiment may include a sensor module.

The illustrated LED lighting system 400B is an integrated system in which the LED array 410 and the circuitry for operating the LED array 410 are provided on a single electronics board. Connections between modules on the same surface of the circuit board 499 may be electrically coupled for exchanging, for example, voltages, currents, and control signals between modules, by surface or sub-surface interconnections, such as traces 431, 432, 433, 434 and 435 or metallizations (not shown). Connections between modules on opposite surfaces of the circuit board 499 may be electrically coupled by through board interconnections, such as vias and metallizations (not shown).

According to embodiments, LED systems may be provided where an LED array is on a separate electronics board from the driver and control circuitry. According to other embodiments, a LED system may have the LED array together with some of the electronics on an electronics board separate from the driver circuit. For example, an LED system may include a power conversion module and an LED module located on a separate electronics board than the LED arrays.

According to embodiments, an LED system may include a multi-channel LED driver circuit. For example, an LED module may include embedded LED calibration and setting data and, for example, three groups of LEDs. One of ordinary skill in the art will recognize that any number of groups of LEDs may be used consistent with one or more applications. Individual LEDs within each group may be arranged in series or in parallel and the light having different color points may be provided. For example, warm white light may be provided by a first group of LEDs, a cool white light may be provided by a second group of LEDs, and a neutral white light may be provided by a third group.

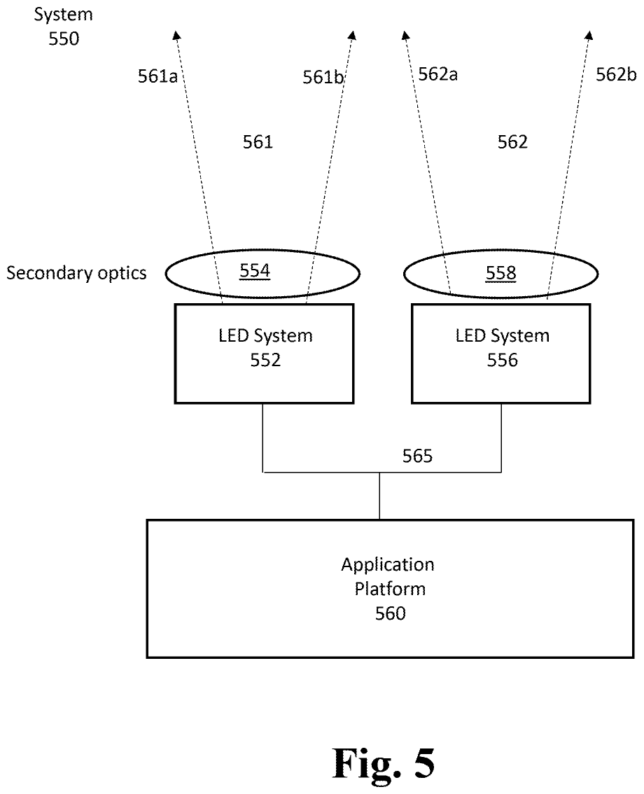

FIG. 5 shows an example system 550 which includes an application platform 560, LED systems 552 and 556, and secondary optics 554 and 558. The LED systems 552 and 556 may include LED sub-assembly 30 and lead frame 20, as shown in FIGS. 1A and 1B. The LED System 552 produces light beams 561 shown between arrows 561a and 561b. The LED System 556 may produce light beams 562 between arrows 562a and 562b. In the embodiment shown in FIG. 5, the light emitted from LED system 552 passes through secondary optics 554, and the light emitted from the LED System 556 passes through secondary optics 558. In alternative embodiments, the light beams 561 and 562 do not pass through any secondary optics. The secondary optics may be or may include one or more light guides. The one or more light guides may be edge lit or may have an interior opening that defines an interior edge of the light guide. LED systems 552 and/or 556 may be inserted in the interior openings of the one or more light guides such that they inject light into the interior edge (interior opening light guide) or exterior edge (edge lit light guide) of the one or more light guides. LEDs in LED systems 552 and/or 556 may be arranged around the circumference of a base that is part of the light guide. According to an implementation, the base may be thermally conductive. According to an implementation, the base may be coupled to a heat-dissipating element that is disposed over the light guide. The heat-dissipating element may be arranged to receive heat generated by the LEDs via the thermally conductive base and dissipate the received heat. The one or more light guides may allow light emitted by LED systems 552 and 556 to be shaped in a desired manner such as, for example, with a gradient, a chamfered distribution, a narrow distribution, a wide distribution, an angular distribution, or the like.

In example embodiments, the system 550 may be a mobile phone of a camera flash system, indoor residential or commercial lighting, outdoor light such as street lighting, an automobile, a medical device, AR/VR devices, and robotic devices. The integrated LED lighting system shown in FIG. 3, LED System 400A shown in FIG. 4A, illustrate LED systems 552 and 556 in example embodiments.

In example embodiments, the system 550 may be a mobile phone of a camera flash system, indoor residential or commercial lighting, outdoor light such as street lighting, an automobile, a medical device, AR/VR devices, and robotic devices. The LED System 400A shown in FIG. 4A and LED System 400B shown in FIG. 4B illustrate LED systems 552 and 556 in example embodiments.

The application platform 560 may provide power to the LED systems 552 and/or 556 via a power bus via line 565 or other applicable input, as discussed herein. Further, application platform 560 may provide input signals via line 565 for the operation of the LED system 552 and LED system 556, which input may be based on a user input/preference, a sensed reading, a pre-programmed or autonomously determined output, or the like. One or more sensors may be internal or external to the housing of the application platform 560.

In various embodiments, application platform 560 sensors and/or LED system 552 and/or 556 sensors may collect data such as visual data (e.g., LIDAR data, IR data, data collected via a camera, etc.), audio data, distance based data, movement data, environmental data, or the like or a combination thereof. The data may be related a physical item or entity such as an object, an individual, a vehicle, etc. For example, sensing equipment may collect object proximity data for an ADAS/AV based application, which may prioritize the detection and subsequent action based on the detection of a physical item or entity. The data may be collected based on emitting an optical signal by, for example, LED system 552 and/or 556, such as an IR signal and collecting data based on the emitted optical signal. The data may be collected by a different component than the component that emits the optical signal for the data collection. Continuing the example, sensing equipment may be located on an automobile and may emit a beam using a vertical-cavity surface-emitting laser (VCSEL). The one or more sensors may sense a response to the emitted beam or any other applicable input.

In example embodiment, application platform 560 may represent an automobile and LED system 552 and LED system 556 may represent automobile headlights. In various embodiments, the system 550 may represent an automobile with steerable light beams where LEDs may be selectively activated to provide steerable light. For example, an array of LEDs may be used to define or project a shape or pattern or illuminate only selected sections of a roadway. In an example embodiment, Infrared cameras or detector pixels within LED systems 552 and/or 556 may be sensors that identify portions of a scene (roadway, pedestrian crossing, etc.) that require illumination.

One of ordinary skill in the art would recognize from the present embodiments that the method and configuration described herein can be applied to any LED architecture.

The present embodiments can be implemented using standard manufacturing equipment according to known LED production assemblies and methods. The present embodiments can be incorporated into a modified flow of existing manufacturing process in LED die production.

The non-limiting methods and embodiments described herein for an LED assembly may be modified for a variety of applications and uses while remaining within the spirit and scope of the claims. The implementations and variations described herein, and/or shown in the drawings, are presented by way of example only and are not limiting as to the scope and spirit.

The descriptions herein may be applicable to all implementations of the method and system described herein although it may be described with respect to a particular implementation.

As described herein, the methods disclosed herein are not limited to any particular element(s) that perform(s) any particular function(s) and some steps of the methods presented need not necessarily occur in the order shown. For example, in some cases two or more method steps may occur in a different order or simultaneously.

In addition, some steps of the described methods may be optional (even if not explicitly stated to be optional) and, therefore, may be omitted. These and other variations of the methods disclosed herein will be readily apparent, especially in view of the description of the methods described herein, and are considered to be within the full scope of the embodiments.

Some features of implementations may be omitted or implemented with other implementations. The device or system elements and method elements described herein may be interchangeable and used in or omitted from any of the examples or implementations described herein.

Although features and elements are described above in particular combinations, each feature or element can be used alone without the other features and elements or in various combinations with or without other features and elements.

Having described the embodiments in detail, those skilled in the art will appreciate that, given the present description, modifications may be made to the embodiments described herein without departing from the spirit of the inventive concept. Therefore, it is not intended that the scope of the invention be limited to the specific embodiments illustrated and described.

What is claimed is:

1. A method of forming a light emitting diode (LED) device, the method comprising:
providing:
a lead frame, and
an LED sub-assembly comprising an LED die; and
an optically transparent side wall surrounding the LED die, the side wall having a curved or angled profile;
attaching the LED sub-assembly to the lead frame; and
dispensing an encapsulation material in a space surrounding the LED sub-assembly attached to the lead frame.

2. The method of claim 1, wherein the LED die is attached to a wavelength converting layer.

3. The method according to claim 1, wherein the encapsulation material includes a polymeric material mixed with reflective particles.

4. The method according to claim 1, wherein the encapsulation material includes silicone mixed with titanium oxide (TiOx) particles.

5. The method according to claim 2, wherein the encapsulation material peripherally surrounds both the wavelength converting layer and the side wall after dispensing the encapsulation material.

6. The method according to claim 2, wherein the wavelength converting layer comprises a first surface attached to the LED die and a second surface opposite from the first surface that has a flat profile.

7. The method of claim 1, wherein providing the lead frame further includes at least one of:
etching a metallic layer to form contacts of the lead frame; or
stamping a metallic layer to form contacts of the lead frame.

8. The method of claim 1, wherein the lead frame includes a polymer base and metal contacts embedded in the polymer base.

9. The method of claim 1, wherein a pocket is formed or stamped in the lead frame, and the pocket is adapted to receive the LED sub-assembly.

10. The method of claim 1, wherein the space surrounding the LED sub-assembly has a conical profile.

11. The method of claim 1, wherein the space surrounding the LED sub-assembly extends between the LED sub-assembly and an adjacent LED sub-assembly attached to the lead frame.

12. The method of claim 1, wherein the LED sub-assembly is a high powered LED.

13. The method of claim 2, wherein the wavelength conversion layer is formed as a first discrete layer, the LED die is formed as a second discrete layer, and the LED die is deposited onto the wavelength conversion layer.

14. The method of claim 1, wherein the lead frame is formed as a continuously flat plate having a uniform cross-sectional profile.

15. The method of claim 1 further comprising:
curing the encapsulation material.

16. The method of claim 1, wherein attaching the LED sub-assembly to the lead frame comprises at least one of a soldering, a mounting by conductive epoxy, and mounting by sintering heat and electrically conductive material.

17. A light emitting diode (LED) device comprising:
a lead frame including a polymeric base and at least one metal contact;
an LED sub-assembly including an LED die attached to an optically transparent side wall surrounding the LED die, the optically transparent side wall having a curved or angled profile, the LED sub-assembly being attached to the lead frame such that at least one metal contact of the LED die contacts the at least one metal contact of the lead frame; and
an encapsulation material surrounding the LED sub-assembly.

18. The LED device of claim 17, further comprising a wavelength conversion layer, wherein the wavelength conversion layer defines a first surface attached to the LED die and a second surface opposite from the first surface that has a flat profile.

19. The LED device of claim 17, wherein at least one of:
the encapsulation material includes at least one of a polymeric and a silicone based material mixed with reflective particles, and
the encapsulation material peripherally surrounds both the wavelength converting layer and the optically transparent side wall.

20. The LED device of claim 17, wherein the polymer base of the lead frame is formed as at least one of: a continuously flat plate having a uniform cross-sectional profile; or a plate including a pre-molded pocket adapted to receive the LED sub-assembly.
